(19) United States
(12) Patent Application Publication
(10) Pub. No.: US 2016/0344087 A1
(43) Pub. Date: Nov. 24, 2016

(54) Combiner arrangement

(71) Applicants: Sergei Kolesov, Gevelsberg (DE); Helmut Piel, Wuppertal (DE)

(72) Inventors: Sergei Kolesov, Gevelsberg (DE); Helmut Piel, Wuppertal (DE)

(73) Assignee: Cryoelectra GmbH, Wuppertal (DE)

(21) Appl. No.: 15/157,530

(22) Filed: May 18, 2016

(30) Foreign Application Priority Data
May 18, 2015 (DE) 10 2015 107 729.9

(51) Int. Cl. H01P 5/18; H03H 7/38

(52) U.S. Cl. CPC H01P 5/183; H01P 5/188; H03H 7/383

(57) ABSTRACT

The present invention relates inter alia to a combiner arrangement for combining a plurality of high-frequency input signals into a high-frequency output signal comprising at least two primary combiners for combining at least two high-frequency input signals into a high-frequency intermediate signal and a secondary combiner for combining the high-frequency intermediate signals from the primary combiners into the high-frequency output signal. The task of enabling a compact design along with combination losses that are as low as possible and easy accessibility of the components is achieved in that the secondary combiner comprises a coupler for combining the high-frequency intermediate signals of the primary combiners.

### CROSS-REFERENCE TO RELATED PATENT APPLICATIONS

This patent application claims priority to German Application No. 10 2015 107 729.9, filed May 18, 2015, the entire teachings and disclosure of which are incorporated herein by reference thereto.

### BACKGROUND OF THE INVENTION

The development of high-performance amplifiers in the high-frequency range (particularly in the VHF and UHF range) has received a strong boost through the development and improvement of LDMOS (‘laterally diffused metal oxide semiconductor’) FETs (field effect transistors). Power amplifier units comprising two push-pull transistors with a high-frequency output of the transistor pair of 750 watt in the frequency range between 50 and 500 MHz can be provided, for example. This is the frequency range in which the high-frequency acceleration resonators of virtually all circular particle accelerators (for example, synchrotrons and cyclotrons) are operated. High-frequency outputs typically between 150 kW and 300 kW are required to set up and maintain the electrical acceleration fields in such resonators.

However, such high outputs can only be achieved with semiconductor amplifiers if the output signals from more than a hundred amplifier units are combined with the help of combiners. Working on the premise, for example, that a high-frequency output of approx. 625 W can be generated using such a state-of-the-art amplifier unit, then four of said amplifier units can provide an output of 2.5 kW. However, in order to ultimately achieve the required output power referred to above, of 150 kW for example, a sixty fold combiner is still required, in other words a combiner that combines 60 individual signals into one output signal. Combining said signals is no longer possible due to the high outputs in planar technology.

Consequently, combining takes place according to the state of the art in the high-frequency range through a system of waveguides for electro-magnetic waves, i.e. spatial structures in which electro-magnetic waves can propagate in a guided manner. Such waveguides can be configured as coaxial conductors, for example, with an inner conductor and an outer conductor, or as a hollow conductor. Coaxial combiners are used particularly in the VHF range (‘very high frequency’, frequencies between 30 MHz and 300 MHz), whereas waveguide or hollow conductor combiners are used particularly in the UHF range (‘ultra high frequency’, frequencies between 300 MHz and 3 GHz) due to the power losses in coaxial cables, for instance.

In the VHF range, the signals consist of electro-magnetic waves with (vacuum) wavelengths between 1 m and 10 m, for example. Since the components of corresponding VHF coaxial combiners are in the order of magnitude of the wavelengths (for example, in λ/4 transformers), VHF coaxial combiners can become impractically long and take up a lot of space accordingly.

A generic combiner arrangement is known from DE 10 2013 102 552 B3, for example, which combines a plurality of high-frequency input signals into a high-frequency output signal. Here the signals to be combined are combined in several stages by means of combiners. Two sets of elongated primary combiners are provided here, which are each arranged on a plane like a cartwheel or in a star shape, and lead centrally to a secondary combiner which is arranged perpendicular to the primary combiners. The power of the secondary combiner is then decoupled by means of a further combiner. Although the circular arrangement of the control cabinets enables easy access, this leads to a comparatively large-scale arrangement.

One solution, for example, would be to provide a combiner arrangement with radial geometry (i.e. a combiner, which guides signals inwards through a disc-shaped waveguide of the combiner in order to combine said signals). The signals are coupled, for example, at positions distributed symmetrically over an edge portion of the disc-shaped waveguide and decoupled in the centre of the disc-shaped waveguide. In order to prevent unwanted reflections in the process, a conical (rising from the edge to the centre) base plate could be provided in combination with a planar top panel for the disc-shaped waveguide. It is possible to imagine a model of the disc-shaped waveguide divided into segments, wherein a coupled signal is propagated by a waveguide segment and then subsequently decoupled. The model concept can be motivated by considerations of the electrical current flow that is present. In this model concept, for the signals propagating radially inwards, not only the width of the waveguide segment (which therefore represents the respective segment of the disc-shaped waveguide, to which segment a signal coupled to the waveguide is assigned) is reduced, but also its height. Since the waveguide impedance of a waveguide segment of this type is proportional to the ratio between the height and width of the waveguide geometry, the conicity (i.e. decreasing height towards the centre of the waveguide) of the base plate can compensate for a reduction in the width of the waveguide segment to the centre thereof and the waveguide impedance remains constant in a radial direction. Unwanted reflections as a result of incorrect adaptions can thus be prevented. However, since waveguide impedance generally has to be adjusted by λ/4 transformers, this would lead to combiner arrangements with diameters of several metres in the VHF range described. For example, a disc-shaped parallel plate waveguide (with conical base plate) would have to have a diameter (2*r) of over 2 m (2*λ/4) at a frequency of 70 MHz, for instance. Such geometries would therefore only be realised in a space-saving manner at comparably high frequencies (such as in the case of microwaves).

Consequently, there is a need to further reduce the space required for the combiners. However, access to the individual amplifier units should still be possible to enable easier replacement of the amplifier units. Combination losses also need to be kept to a minimum in order to achieve a degree of efficiency that is as high as possible.

### BRIEF SUMMARY OF THE INVENTION

In the light of this, the task of the invention is to suggest a combiner arrangement, a system and a method wherein a compact design is possible, but at the same time combination losses are kept to a minimum and there is easy access to the components.

This problem is solved in a combiner arrangement according to a first aspect in that the secondary combiner comprises a coupler for combining the high-frequency intermediate signals of the primary combiners.

In a system according to a second aspect, the problem is solved in that the system comprises a combiner arrangement according to the first aspect.

In a method according to a third aspect, the problem is solved in that the high-frequency intermediate signals of the primary combiners are combined by means of a coupler of the secondary combiner.

According to the first aspect, the present invention relates to a combiner arrangement for combining a plurality of high-frequency input signals into a high-frequency output signal comprising: at least two primary combiners for combining at least two high-frequency input signals with a high-frequency intermediate signal and a secondary combiner for combining the high-frequency intermediate signals of the primary combiners with the high-frequency output signal.

According to the second aspect, the invention relates to a system comprising a plurality of amplifier units for generating the high-frequency input signals.

According to the third aspect, the invention relates to a method for combining a plurality of high-frequency input signals with a high-frequency output signal, in particular with a combiner arrangement according to the first aspect comprising the steps: combining at least two high-frequency input signals into a high-frequency intermediate signal by means of at least two primary combiners and combining the high-frequency intermediate signals of the primary combiners into the high-frequency output signal by means of a secondary combiner.

It has been assumed previously in the prior art that combining the high-frequency input signals already combined into high-frequency intermediate signals by the primary combiners by means of a space-saving coupler having a disc-shaped geometry, for instance, is not possible. This is due to the fact that combining at the second combiner level requires the use of a comparatively large coupler in order to combine the high-frequency signals, particularly in the case of high outputs. The main problem here is that when using such couplers, if they are to be designed to save space accordingly, the waveguide impedances can no longer be calculated analytically. If a plurality of high-frequency intermediate signals are directed through the coupler of the secondary combiner, for example from the outside to the inside, a high-frequency intermediate signal will be directed from the outside to the inside effectively in a tapering coupler segment. It has been assumed that such geometries of the secondary combiner along with large coupler designs (viewed in comparison with the wavelength of the high-frequency signals), which are necessary for a secondary combiner in the case of high-frequency signals, cannot be used for effective combination of the high-frequency intermediate signals. Adequate calculation of the characteristics of such geometries is not possible either.

The aspects of the invention turn against these assumptions from the prior art. It has become evident that a secondary combiner, which comprises a coupler for combining the high-frequency intermediate signals from the primary combiners, not only enables a compact design with easy accessibility to the amplifier units, but, contrary to expectations, also allows the achievement of minimal combination losses.

The combiner arrangement or parts thereof can be simulated for this purpose, for example, using a finite element method (FEM) for instance. As a result, the specific geometry of the coupler for combining the high-frequency intermediate signals from the primary combiners can be determined on an individual basis.

Providing a coupler allows a cable-free connection to be provided between the primary combiners and the coupler of the secondary combiner. The primary combiners are flanged onto the coupler, for example.

As in the field of high-frequency technology, a combiner is understood in the present context as a device that combines a plurality of weaker signals, particularly of the same frequency, into a stronger signal. The combiner preferably isolates its inputs from each other in the process so that these do not influence each other or the other signal generators that provide the high-frequency input signals.

As in the field of electrical engineering, high-frequency describes the frequency range between 9 kHz and long-wave light (THz range). It should therefore also include the VHF range (very high frequency) with frequencies of between 30 MHz and 300 MHz (or wavelengths of between 10 m and 1 m respectively) and the UHF range (ultra high frequency) with frequencies between 300 MHz and 3 GHz (or wavelengths between 1 m and 10 cm, respectively).

Other advantageous embodiments for the different aspects of the invention are explained below.

According to one embodiment of the different aspects of the invention, the coupler of the secondary combiner is disc-shaped. Here, the coupler in the secondary combiner can be configured in the form of a circular disc, for example. This is taken to mean in particular a flat cylinder, particularly a cylinder the radius of which is significantly greater (for example, multiple times, for example at least twice) than the thickness thereof (in the form of a can, for example). Another solution, however, is to configure the coupler of the secondary combiner as a polygonal disc, for example a (straight) prism with a polygon (a square, hexagon, octagon etc., for example) as the base. The coupler can therefore be designed as a cuboid.

According to a preferred embodiment of the different aspects of the invention, the secondary combiner is configured, particularly through its geometry, such that an at least partial compensation of the high-frequency signals reflected in the secondary combiner is achieved. Preferably, the high-frequency signals reflected in the secondary combiner (due to the geometry of the coupler, for example) are compensated by a further reflection of high-frequency signals in the secondary combiner.

Compensation is taken to mean that different influences of a physical variable (for example, a high-frequency signal) work against each other on account of technical factors or their physical form (for example, the geometry and physical characteristics of the combiner arrangement) such that they eliminate one another. If an influence is assessed as interference (such as, for example, a high-frequency signal reflected back to the primary combiner), then the aim of compensation is to counter the unwanted influence with a second one which is designed to eliminate or reduce the original influence.

In this way, a reflection of signals back to the primary combiner can be prevented at least partially (or fully). This means that although there is an (unwanted or unavoidable) reflection of high-frequency signals in the secondary combiner, the primary combiner does not see or sense said reflections or only in a reduced manner. As a result, the combiner inputs can be effectively isolated from each other and a high degree of efficiency of the combiner arrangement can be achieved. For example, unwanted or (due to the geometry of the coupler, which causes a change in the wave impedance along the signal propagation path) unavoidable reflection of high-frequency signals in the secondary combiner is compensated by a specific or intentional (but essentially avoidable) further reflection of high-frequency signals in the secondary combiner.

The reflected high-frequency signals can be (partially) reflected high-frequency intermediate signals and/or high-frequency output signals for example. For example, a first reflected high-frequency signal is a high-frequency signal reflected at a first location or in a first region (for example, in the region of the coupler) of the secondary combiner and a further reflected high-frequency signal is a high-frequency signal reflected at a second location or in a second region of the secondary combiner.

It has become evident that in a coupler in which the high-frequency signals run radially inwards, i.e. propagate in the direction of the central point of the coupler, a continuous reflection of said signals occurs in the propagation process. At least partial compensation of said continuous reflection can be achieved through a further reflection of the high-frequency output signal in the secondary combiner.

For example, the influences of the reflected high-frequency signals are cancelled out at a (further) location or in a (further) region if the reflected high-frequency signals interfere in a destructive manner, for example in the respective transition region between the primary combiner and the secondary combiner.

Compensation can occur through specific adjustment of the secondary combiner. Specific adjustment of or change in the waveguide impedance of the secondary combiner is performed, for example. Any change in impedance in the secondary combiner causes a reflection. The change is then designed such that a reflected wave is generated as a result, which compensates through interference the reflected wave also occurring in the transition region between the primary combiner and the secondary combiner, which is generated through the propagation of the high-frequency signals by the coupler. An adjustment of or change to the geometry (for example, the length) of the secondary combiner is made for this purpose. An adjustment or change is made to the geometry of the external or internal conductor in the secondary combiner (through a change to the cross-section, for example). The specific reflection of the high-frequency output signal described can take place as a result of this, which can (partially) compensate the reflected high-frequency intermediate signals.

According to a preferred embodiment of the different aspects of the invention, at least one characteristic geometric extension of the coupler of the secondary combiner is not insignificant compared with the wavelength of the high-frequency input signals and/or the high-frequency output signal.

A characteristic geometrical extension is taken to mean an extension of the diameter or radius of the coupler of the secondary combiner, for example. An insignificant extension compared with the wavelength is taken in particular to mean that the extension essentially has no significance or only minor significance compared to other influencing factors or does not play a crucial role for one or more relevant characteristics of the combiner arrangement (in particular low combination losses or high degree of effectiveness).

In the event that the coupler of the secondary combiner is (circular) disc-shaped, the radius of the coupler of the secondary combiner is, for example, at least 2%, preferably at least 5%, further preferred at least 7% of the wavelength of the high-frequency input signals and/or the high-frequency output signal. For example, the radius of the disc-shaped coupler of the secondary combiner is at least 10 cm, preferably at least 20 cm and particularly preferred at least 30 cm.

As pointed out above, it has become evident that in spite of the significant size of the coupler of the secondary combiner, a compact combiner arrangement with unexpectedly low combination losses can be provided.

According to a preferred embodiment of the different aspects of the invention, the primary combiners are each configured substantially elongated wherein the primary combiners preferably run substantially parallel and/or substantially perpendicular to the coupler of the secondary combiner.

Such an embodiment of the primary combiners allows a particularly compact arrangement to be achieved in combination with the coupler of the secondary combiner. A respective primary combiner constitutes a substantially elongated wave guide for conducting the high-frequency intermediate signals from an end of the primary combiner facing away from the coupler of the secondary combiner to an end of the primary combiner facing the coupler of the secondary combiner. The primary combiners have a substantially round cross-section, at least in sections, and are configured as substantially cylindrical at least in sections.

According to a preferred embodiment of the different aspects of the invention, the secondary combiner has a substantially elongated line section, which preferably runs substantially parallel to the primary combiners and/or is substantially perpendicular to the coupler of the secondary combiner.

Moreover, such an embodiment of the secondary combiner reduces the space required by the combiner arrangement. The substantially elongated line section can be used advantageously to conduct the high-frequency output signal. For example, the substantially elongated line section serves to conduct the high-frequency output signal from an end facing the coupler of the secondary combiner to an end of the substantially elongated line section of the secondary combiner facing away from the coupler of the secondary combiner. The substantially elongated line section of the secondary combiner can also be advantageously used to decouple the output signal from the secondary combiner. Furthermore, the substantially elongated line section can also be used to adjust the waveguide impedance. A transformer section (for example, a λ/4 transformer) can be provided for this purpose for example. This can increase the degree of efficiency of the combiner arrangement.

The substantially elongated line section of the secondary combiner has a substantially round cross-section, at least in sections, and is configured substantially cylindrical at least in sections. The substantially elongated line section of the secondary combiner is longer than the substantially elongated primary combiners for example. The substantially elongated line section of the secondary combiner is flanged onto the coupler of the secondary combiner.

In a particularly preferred embodiment, the primary combiners and the substantially elongated line section of the secondary combiner are arranged on the same side of the coupler of the secondary combiner. This further reduces the space requirement of the combiner arrangement. For easy accessibility, the high-frequency signals can be coupled on the side of the coupler of the secondary combiner on which the high-frequency output signal can also be decoupled. However, another solution is that the substantially elongated line section of the secondary combiner is arranged on a first side of the coupler of the secondary combiner and the primary combiners are arranged exclusively (or additionally to primary combiners on the first side) on a second side of the coupler of the secondary combiner opposite the first side. The primary combiners arranged on the second side then run anti-parallel to the secondary combiner.

With regard to at least partial compensation of high-frequency signals reflected in the secondary combiner to which reference has already been made, there may be an (unwanted) first (at least partial) reflection of the high-frequency intermediate signals in the region of the coupler. For example, a continuous reflection of the high-frequency signals takes place during propagation by the coupler. Furthermore, the secondary combiner can be configured such that a (specific) further (at least partial) reflection of the high-frequency output signal takes place in the substantially elongated line section of the secondary combiner (at an end facing away from the coupler, for example). The first reflected high-frequency signal and (at least) the further reflected high-frequency signal then compensate each other at least in part, for example in the transition region between the respective primary combiner and the secondary combiner.

According to a preferred embodiment of the different aspects of the invention, the substantially elongated line section of the secondary combiner is arranged centrally on the coupler of the secondary combiner (in the centre of a circular disc-shaped coupler of the secondary combiner, for example) and preferably the primary combiners are arranged around the substantially elongated section of the secondary combiner on the coupler of the secondary combiner.

A further reduced space requirement of the combiner arrangement is achieved through this with higher degrees of efficiency. For example, the primary combiners are arranged in a circular manner around the substantially elongated line section of the secondary combiner. For example, the primary combiners are arranged equidistant from each other and/or from the substantially elongated line section of the secondary combiner.

For example, the coupler of the secondary combiner can be divided into a whole number ‘n’ of substantially congruent coupler segments, where n is the number of primary combiners, i.e. the number of high-frequency intermediate signals. For example, the primary combiners are each connected with the secondary combiner in one of the n congruent coupler segments. For instance, the combiner arrangement is therefore rotationally symmetric about an n-fold rotation axis (around the substantially elongated line section of the secondary combiner, for example).

According to a preferred embodiment of the different aspects of the invention, the primary combiners and/or secondary combiner are configured as coaxial conductors, at least in sections.

Combiner arrangements with high degrees of efficiency can be achieved particularly at frequencies in the VHF range. The primary combiners and/or secondary combiner can be configured as aerial conductors, for example, at least in sections. This is taken to mean a coaxial electric conductor, which does not contain any dielectric supports at least in sections for mounting the inner conductor, but rather air. Due to the extremely precise known permittivity of air, the waveguide impedance can be accurately set through precise mechanical dimensions (internal diameter of the external conductor, diameter of the inner conductor).

According to a preferred embodiment of the different aspects of the invention, the primary combiners and/or secondary combiner are dielectrically loaded at least in sections. A dielectric is provided for this purpose, for example. The dielectric can be polytetrafluoroethylene (PFTE), for example.

In particular, the substantially elongated line section of the secondary combiner configured as a coaxial conductor has a dielectric arranged between outer conductor and inner conductor. The dielectric has alternating regions of different thickness, for example. This means that particularly advantageous characteristics of the substantially elongated line section, such as specific adjustment of the waveguide impedance, can be achieved. The section-by-section charging of the primary combiners with a dielectric can reduce the length of the primary combiners and consequently an extremely compact combiner arrangement can be provided.

According to a preferred embodiment of the different aspects of the invention, the coupler of the secondary combiner has a hollow space with an inner coupling conductor arranged therein. The coupler of the secondary combiner may have a housing for this purpose, for example. The hollow space can then be provided by the housing, for example, which can be disc-shaped or can-shaped. As already stated in connection with the coupler of the secondary combiner, the housing can be a circular or polygonal disc. The geometry of the housing and the inner coupling conductor are adapted to each other, for example. The inner coupling conductor can also be configured as disc-shaped, i.e. can be an inner coupling disc, for example a circular or polygonal disc, as already stated in connection with the coupler of the secondary combiner. This allows simple configuration of the coupler as a coplanar wave conductor, wherein the inner coupling conductor functions as an inner conductor and the housing as an outer conductor. Electro-magnetic shielding is achieved as a result of this and emission of high-frequency radiation prevented thus reducing power loss.

According to a preferred embodiment, the coupler of the secondary combiner is configured as a parallel plate conductor. Here, the conductors of the coupler of the secondary combiner are configured as plates running substantially parallel, at least in sections. If the coupler of the secondary combiner has a housing with a coupling conductor arranged therein, for example, the sections of the housing serving as outer conductors and the coupling conductor serving as inner conductor run substantially parallel to each other in order to form a coupler which can be regarded as a shielded parallel plate conductor, for example. This means, a conical housing side (for example, a conical base plate of the housing) is not provided in order to obtain an adjustment of the waveguide impedance. In fact, an adjustment of the waveguide impedance in the coupler of the secondary combiner is not necessary as reflections, which are caused by a lack of adjustment of the waveguide impedance, can be compensated by means of specific further reflections as described above. Generally, however, a conical housing side can also be additionally provided in order to achieve an adjustment of the waveguide impedance.

According to a preferred embodiment of the different aspects of the invention, the primary combiners, at least in part, preferably each have a collector section with connections for coupling the high-frequency input signals.

The collector sections are configured substantially elongated, for example. The connections for coupling the high-frequency input signals are set up for a detachable connection. For example, the connections allow coaxial cables to be connected to the collector section of the respective primary combiner. Preferably, the number of connections corresponds to the number of high-frequency input signals. The collector sections are, for example, each arranged on an end of the respective primary combiner facing away from the coupler of the secondary combiner. This enables easy access to the connections.

According to a preferred embodiment of the different aspects of the invention, the collector sections of the primary combiners at least in part, preferably each have an in particular disc-shaped coupler for combining the high-frequency input signals.

This allows the combination of the input signals in the respective primary combiner without high combination losses. In contrast to the coupler of the secondary combiner, the characteristic geometric extension of the respective coupler of the primary combiners is insignificant compared with the wavelength of the high-frequency input signals. Thus, the couplers in the primary combiners can be assumed to be punctiform.

In the event that the couplers of the primary combiners are configured in the shape of a (circular) disc, the radius of the disc-shaped coupler of the primary combiners is at most 7%, preferably at most 5% and further preferred at most 2% of the wavelength of the high-frequency input signals. For example, the radius of the disc-shaped coupler of the primary combiners is at most 30 cm, preferably at most 20 cm, particularly preferred at most 10 cm.

According to a preferred embodiment of the different aspects of the invention, the primary combiners preferably each have, at least in sections, a transformer section for adjusting the waveguide impedance, wherein the waveguide impedance is preferably adjusted in stages.

The waveguide impedance of the primary combiners can thus be adjusted such that a reflection of the respective high-frequency intermediate signal in the transition region between the respective primary combiner and the secondary combiner is reduced or prevented. The transformer sections can each be adjacent to the respective collector sections, for example.

As a result of the connection of a plurality of high-frequency input signals (by means of n cables on the collector, for example), each of said cables on the collector sees an input impedance of 1/n of the waveguide impedance of the cables (50 Ω/n, for example). Said waveguide impedance now needs to be transformed again into the required output wave impedance (son, for example). This can take place by means of the transformer section. This is a λ/4 transformer, for example. A λ/4 transformer is generally a conductor having the length λ/4 and an impedance of the root of the product of input wave impedance and output wave impedance (i.e. root (50 Ω/n×50Ω) for example).

An additional ‘stepped-impedance design’, through a stepped change in the diameter of the inner or outer conductor, for example, can reduce the space required by the combiner arrangement as the primary combiners can be configured shorter.

Preferably the transformer sections of the primary combiners are at least in part, preferably each dielectrically loaded at least in sections. A dielectric is provided for this purpose, for example. In particular, the transformer sections of the primary combiners configured as coaxial conductors each have a dielectric arranged between outer conductor and inner conductor. The loading in sections of the transformer sections of the primary combiners with a dielectric can reduce the length of the primary combiners in particular.

According to a preferred embodiment of the different aspects of the invention, the primary combiners at least in part, preferably each have integrated, preferably bidirectional couplers.

The output line of the primary combiners and/or the strength of a signal potentially reflected from the secondary combiner can be measured by the directional couplers. The directional couplers can each connect to the respective transformer sections, for example.

According to a preferred embodiment of the different aspects of the invention, the combiner arrangement is configured to provide a high-frequency output signal with an output of at least 50 kW, preferably at least 80 kW, particularly preferred at least 150 kW.

It has become evident that the combiner arrangement enables the combination of high-frequency input signals into a high-frequency output signal with such high outputs in a space-saving manner with a high degree of efficiency. Thus is it possible to make the required high-frequency output available to particle accelerator, for example.

In this respect, a use of the combiner arrangement according to the first aspect for providing a high-frequency output signal with an output of at least 50 kW, preferably at least 80 kW, particularly preferred at least 150 kW, is disclosed as a further aspect of the invention.

According to a preferred embodiment of the different aspects of the invention, the combiner arrangement is configured to combine high-frequency input signals, particularly of the same phase and/or same amplitude, with an output of at least 1 kW, preferably at least 2 kW, particularly preferred of at least 2.5 kW.

As shown above, the combiner arrangement advantageously facilitates the combination of high-frequency input signals with such high outputs in a space-saving manner with a high degree of efficiency. Thus high outputs can be achieved for the high-frequency output signals accordingly.

In this respect, a use of the combiner arrangement according to the first aspect for combining high-frequency input signals, in particular of the same phase and/or same amplitude, with an output of at least 1 kW, preferably at least 2 kW, particularly preferred at least 2.5 kW is disclosed as a further aspect of the invention.

According to a preferred embodiment of the different aspects of the invention, the combiner arrangement is configured to combine high-frequency input signals with a frequency of at least 30 MHz, preferably at least 50 MHz, particularly preferred at least 70 MHz and/or at most 500 MHz, preferably at most 300 MHz, particularly preferred at most 100 MHz.

The high-frequency intermediate signals and the high-frequency output signal then also have a frequency in this range, for example the same frequency as the high-frequency input signals. The combiner arrangement makes it possible, particularly in said high-frequency range (particularly in the lower VHF range) to combine high-frequency input signals with comparatively large wavelengths in a space-saving manner with a high degree of efficiency. A frequency of 352 MHz, 118 MHz or 72 MHz (for example, 72.3 MHz) is used for instance.

In this respect, a use of the combiner arrangement according to the first aspect for combining high-frequency input signals with a frequency of at least 30 MHz, preferably at least 50 MHz, particularly preferred at least 70 MHz and/or at most 500 MHz, preferably at most 300 MHz, particularly preferred at most 100 MHz, is disclosed as a further aspect of the invention.

According to a preferred embodiment of the different aspects of the invention, at least four, preferably at least six primary combiners are provided for combining the at least two, preferably at least five, particularly preferred at least ten high-frequency input signals into the respective high-frequency intermediate signal.

The selection of the number of primary combiners, which also determines the number of high-frequency intermediate signals to be combined and the selection of the number of high-frequency input signals to be combined per primary combiner must be taken into account when designing the combiner arrangement. It has become evident that a respective number is advantageous in terms of compact design and low combination losses.

According to a preferred embodiment of the different aspects of the invention, the primary combiners and/or the secondary combiner, in particular the coupler of the secondary combiner, are made at least in part of copper and/or aluminium.

Due to their high electrical conductivity, copper and aluminium are particularly suitable for economical production of a highly efficient combiner arrangement. The inner coupling conductor of the coupler of the secondary combiner is made of aluminium or copper, for example. Other parts of the coupler of the secondary combiner, a housing arranged around the inner coupling conductor, for example, can also be made of aluminium or copper. Other parts of the combiner arrangement can also be made of aluminium or copper, for example the primary combiners or parts thereof.

In a particularly advantageous embodiment, the inner conductors of the primary combiners configured as coaxial conductors and/or the inner conductor of the secondary combiner configured as coaxial conductor, i.e. in particular the inner coupling conductor of the coupler of the secondary combiner, are made of copper. The inner conductors are soldered together, for example.

In a particularly advantageous embodiment, the outer conductors of the primary combiners configured as coaxial conductors and/or the outer conductors of the secondary combiner configured as coaxial conductors, i.e. in particular the housing of the coupler of the secondary combiner, are made of aluminium.

The combiner arrangement according to the first aspect can be arrangement in a control cabinet. The combiner arrangement according to the first aspect means that it can be constructed in a compact and advantageous manner such that the combiner arrangement can be arranged in a control cabinet and the high-frequency input signals coupled on the front side of the control cabinet or the high-frequency output signal decoupled on the front side of the control cabinet.

With regard to a system according to the second aspect, an amplifier unit can have or one or a plurality of transistors, for example, one or a plurality (for example, four) of push-pull transistor pairs. For example, the transistor signals can be combined using planar technology (e.g. using Wilkinson or hybrid combiners), in order to provide a high-frequency input signal for the combiner arrangement.

The amplifier units can be arranged in one or more control cabinets.

Reference is made in particular to the description of the combiner arrangement according to the first aspect and the embodiments thereof with regard to the advantages and further embodiments of the system according to the second aspect and the method according to the third aspect.

The previous (and following) description of means to carry out a method step should disclose the relevant method step. Also, corresponding means for carrying out the method steps will be disclosed through the disclosure of method steps.

The examples and embodiments of all aspects of the present invention described above should also be understood to be disclosed in all combinations.

Further advantageous embodiments of the different aspects are explained in the following detailed description of a number of example embodiments of the aspects, in particular in combination with the figures. However, the figures enclosed with the application are only intended be used for illustration purposes and not to define the scope of protection of the invention. The enclosed drawings are not necessarily true to scale and are simply intended to reflect in exemplary form the general concept of the present aspects. In particular, features which are contained in the figures should in no way be considered as a necessary element of the present invention.

### BRIEF DESCRIPTION OF THE SEVERAL VIEWS OF THE DRAWING

In the drawings:

FIG. 1a shows a longitudinal representation of an embodiment of a combiner arrangement according to the invention;

FIG. 1b shows a top view of the embodiment from FIG. 1a;

FIG. 2 shows a sectional representation of a further embodiment of a combiner arrangement according to the invention;

FIG. 3 shows two representations of the inner coupling disc; and

FIG. 4 shows the longitudinal representation of the embodiment of the combiner arrangement from FIG. 1 arranged in a control cabinet.

### DETAILED DESCRIPTION OF THE INVENTION

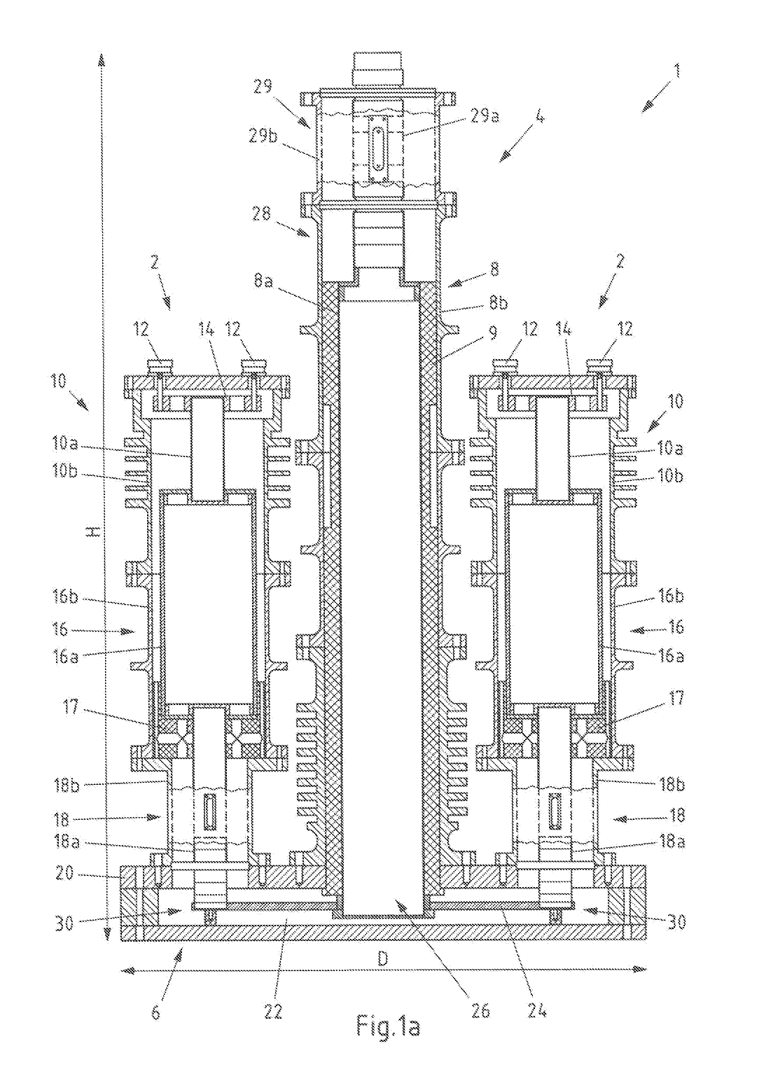

FIG. 1a shows a longitudinal representation of an embodiment of a combiner arrangement 1 according to the invention, while FIG. 1b shows a top view of the embodiment from FIG. 1a. The combiner arrangement 1 is used to combine a plurality of high-frequency input signals into a high-frequency output signal and is configured as a radial combiner. The combiner arrangement 1 shown can combine high-frequency signals with a frequency of 72 MHz, for instance, which corresponds to a wavelength of 4.16 m. In this case, the combiner arrangement can combine a total of 60 high-frequency input signals of 2.5 kW into a high-frequency output signal of 150 kW.

The combiner arrangement 1 has six primary combiners 2 for this purpose in this case, two of which primary combiners can be seen in the sectional representation in FIG. 1. The primary combiners 2 are each used to combine ten high-frequency input signals into a high-frequency intermediate signal and consequently the primary combiners 2 provide a total of six high-frequency intermediate signals.

The combiner arrangement 2 also has a secondary combiner 4, which is used to combine the high-frequency intermediate signals from the primary combiners 2 into a high-frequency output signal. The secondary combiner 4 has a coupler 6 for combining the high-frequency signals from the primary combiners 2. The coupler 6 is configured as disc-shaped in this case. Generally, however, other geometries are possible. The secondary combiner also has an elongated line section 8. The elongated line section 8 of the secondary combiner 4 is arranged centrally here in the region 26 and perpendicular to the disc-shaped coupler 6 of the secondary combiner 4. The elongated line section 8 of the secondary combiner 4 is loaded with a dielectric and has a dielectric 9, which extends over a large portion of the elongated line section 8 of the secondary combiner 4. The dielectric 9 is arranged between the inner conductor 8a and the outer conductor 8b of the elongated line section 8 of the secondary combiner 4. The dielectric 9 has alternating regions of different thickness in this case. The dielectric 9 is polytetrafluoroethylene in this case. The length of the elongated line section 8 can be reduced using the dielectric 9.

The secondary combiner 4 is around 1.20 m high. The diameter D of the disc-shaped coupler 6 in the secondary combiner 4 is around 70 cm.

The primary combiners 2 are also configured in an elongated and cylindrical manner and run parallel to each other and to the elongated and cylindrical line section 8 of the secondary combiner 4. The primary combiners 2 each also stand substantially perpendicular to the disc-shaped coupler 6 in the secondary combiner 4. The primary combiners 2 are arranged around the elongated section 8 of the secondary combiner 4 on the disc-shaped coupler 6 of the secondary combiner 4 (as can be seen in FIG. 1b).

Both the primary combiners 2 and the secondary combiner 4 are configured generally as coaxial conductors. This means that the individual sections of the primary combiners 2 and the individual sections of the secondary combiner 4 generally have inner conductors (10a, 16a, 18a, 24, 8a, 29a) and outer conductors (10b, 16b, 18b, 20, 8b, 29b).

The primary combiners 2 each have a collector section 10 with connections 12 for coupling the high-frequency input signals. The connections 12 are each configured as coaxial connectors and allow the connection of coaxial cables (not shown) for coupling the high-frequency input signals. The primary combiners 2 each have ten of the connections 12 of which only two are shown in the sectional view. The connections 12 are arranged in a circular pattern for example. The collector sections 10 of the primary combiners 2 each have a coupler 14 for combining the high-frequency signals, wherein the coupler 14 is also configured as disc-shaped here. The radius is insignificant as a characteristic geometric extension of the respective disc-shaped coupler 14 in the primary combiners 2 at around 7 cm compared with the wavelength of around 4.16 m of the high-frequency input signals (less than 2% of the wavelength) and consequently the disc-shaped coupler 14 in the primary combiners 2 can be assumed to be punctiform and consequently the behaviour of the high-frequency signals can be calculated analytically.

The primary combiners 2 each have a transformer section 16 for adjusting the waveguide impedance. The transformer sections 16 each connect directly to the collector sections 10 and are connected to the collector sections 10 here by means of a flange connection. The transformer sections 16 mean that the waveguide impedance can be adjusted such that a reflection of the high-frequency intermediate signals back to the primary combiners 2 or to components arranged upstream therefrom is as low as possible (or optimally non-existent). The transformer sections 16 are realised here through coaxial transformers (such as λ/4 transformers). The transformer sections 16 are also realised step-by-step through the transition from inner conductor 10 to inner conductor 16a, which ultimately leads to a length of the transformer sections 16 of less than ¼ of the vacuum wavelength λ. The transformer sections 16 each have a region with a dielectric 17, which is arranged in the region of the transformer section 16 facing the disc-shaped coupler 6 in the secondary combiner. The dielectric 17 is polytetrafluoroethylene in this case. This enables in particular mechanical support and/or reduction of the length of the primary combiners 2.

Bidirectional couplers 18 connect directly to the transformer sections 16 of the primary combiners 2. The directional coupler 18 means that part of the high-frequency intermediate signal conducted in the direction of the secondary combiner 4 can be measured, for monitoring purposes, for example. Secondly, the strength of any signal reflected from the secondary combiner 4 back to the primary combiners 2 can be measured. A bidirectional coupler 29 is also provided on the end 28 of the elongated line section 8 facing away from the disc-shaped coupler 6.

The directional couplers 18 are each directly connected to the disc-shaped coupler 6 in the secondary combiner 4. In region 30, the high-frequency intermediate signals are transmitted from the primary combiners 2 to the disc-shaped coupler 6 of the secondary combiner 4. The disc-shaped coupler 6 of the secondary combiner 4 has a disc-shaped housing 20 with a hollow cavity 22 and an inner coupler conductor in the form of a coupler disc 24 arranged therein, which form a shielded parallel plate conductor. The inner coupler disc 24 serves as an inner conductor of the disc-shaped coupler 6. Unlike the smaller disc-shaped couplers 14 of the primary combiners 2, the radius (35 cm) is significant as a characteristic geometric extension of the larger disc-shaped couplers 6 in the secondary combiner 4 compared with the wavelength (4.16 m) of the high-frequency input signals and/or of the high-frequency output signal (more than 7% of the wavelength). This means that the extension does not just have subordinate importance particularly in respect of low combination losses and high degree of efficiency.

However, due to the complex geometries of the disc-shaped coupler 6, no geometry for adjustment (of the waveguide impedance, for example) can be calculated analytically in order to prevent high-frequency intermediate signals during propagation by the disc-shaped coupler 6 (i.e. from region 30 to region 26). However, the secondary combiner 4 is configured such that high-frequency signals reflected continuously in the disc-shaped coupler 6 in the secondary combiner 4 during propagation are at least partially compensated. The (in part) unwanted reflected high-frequency intermediate signals in the disc-shaped coupler 6 and secondly, the high-frequency output signal (in part) specifically reflected at the end 28 of the elongated line section 8 of the secondary combiner 6 facing away from the disc-shaped coupler 6 compensate each other at least in part. In this case, reflection is achieved through the stepped reduction of the diameter of the inner conductor 8a in the region 28. Generally, it is also possible that reflection is achieved through another geometrical adaptation, for example a change to the diameter of the outer conductor 8b, or by providing a dielectric in the region 28. The compensation, that is to say the destructive interference of the reflected high-frequency signals, takes place in the region 30 in this case. In this manner, a reflection of signals back to the primary combiners 2 can be prevented at least in part.

The design of the secondary combiner 4 and the influences of the individual factors on the design can be simulated using a finite elements method, for example. Thus the required position and shape of the specific reflection of the high-frequency signals in the region 28 can be defined in order to ultimately compensate the unwanted reflection in region 30 that occurs during propagation as a result of the disc-shaped coupler 6.

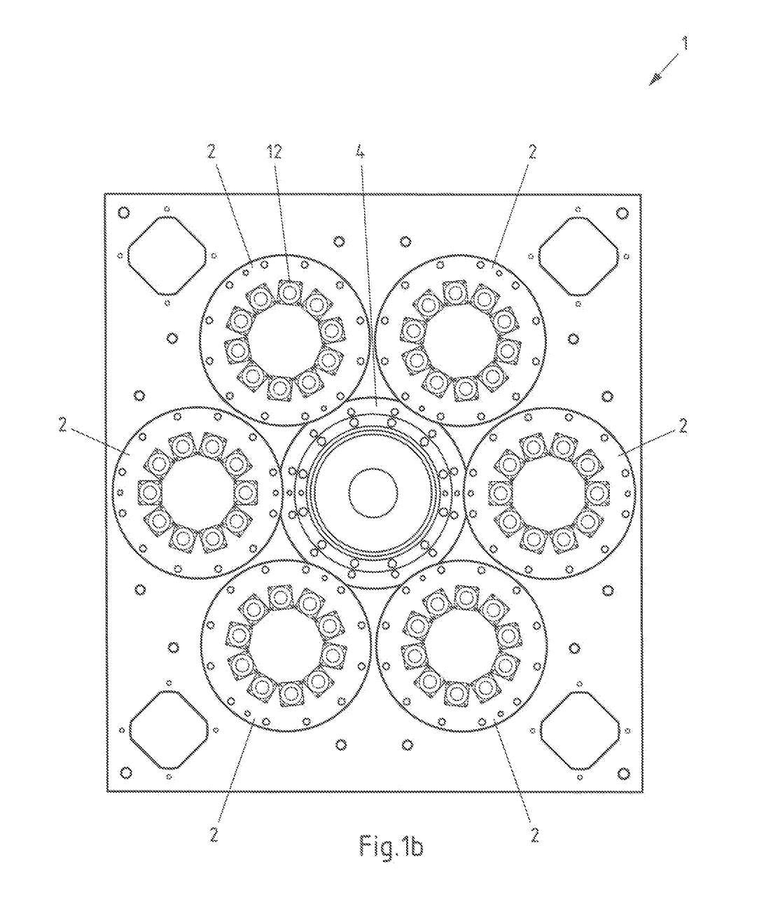

FIG. 2 shows a sectional representation of a further embodiment of a combiner arrangement 1′ according to the invention. The combiner arrangement 1′ differs from combiner arrangement 1 only through the arrangement of the connections 12. These are not on the top side of the cylindrical primary combiners 2 as shown in FIG. 1, but are arranged laterally along the periphery of the cylindrical primary combiners 2. Otherwise, the combiner arrangement 1′ is identical to the combiner arrangement 1. In FIG. 2, however, the circular, uniform arrangement of the six primary combiners 2 about the elongated line section 8 on the disc-shaped coupler 6 is easy to identify. The inner coupler disc 24 is emphasised with hatching in FIG. 2 for better clarification.

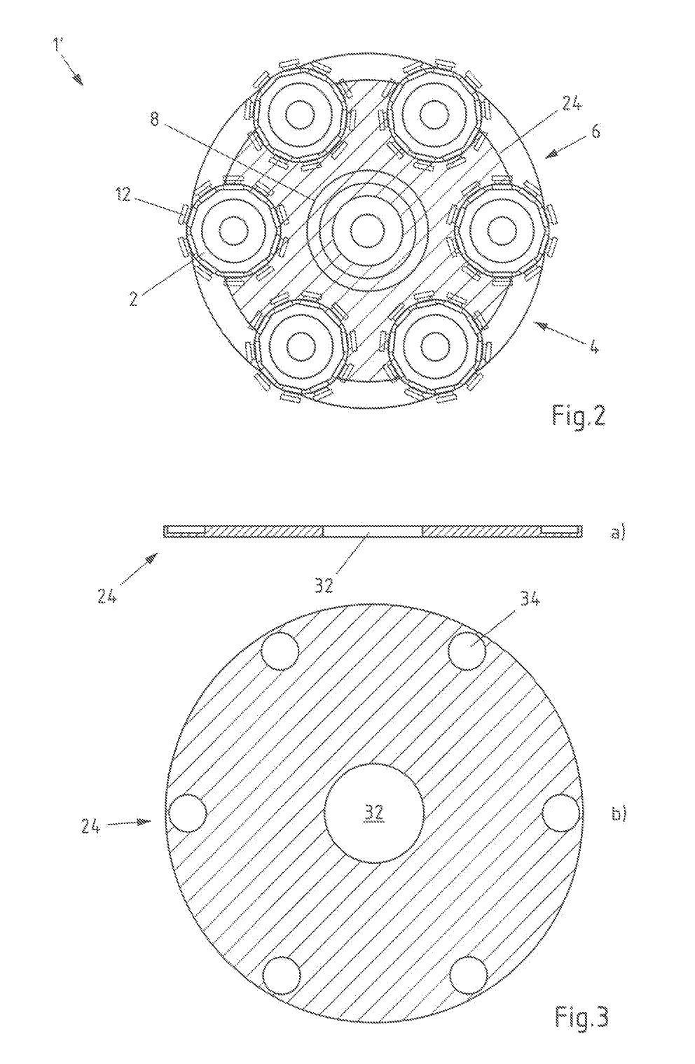

FIG. 3 shows representations of the inner coupler disc 24 in cross-section (FIG. 3a) and top view (FIG. 3b). The inner coupler disc 24 is cylindrical and has a recess 32 in the centre. The elongated line section 8 of the secondary combiner 4 is connected in this region. The inner coupler disc 24 also has six receptacles 34 which are used to connect the six primary combiners 2. The inner coupler disc 24 is made of copper here whereas the housing 20 is made of aluminium.

Furthermore, the outer conductors (10b, 16b, 18b, 20, 8b, 29b) in the primary combiners 2 and the secondary combiner 4 are made of aluminium, whereas the inner conductors (10a, 16a, 18a, 24, 8a, 29a) in the primary combiners 2 and the secondary combiner 4 are made from copper.

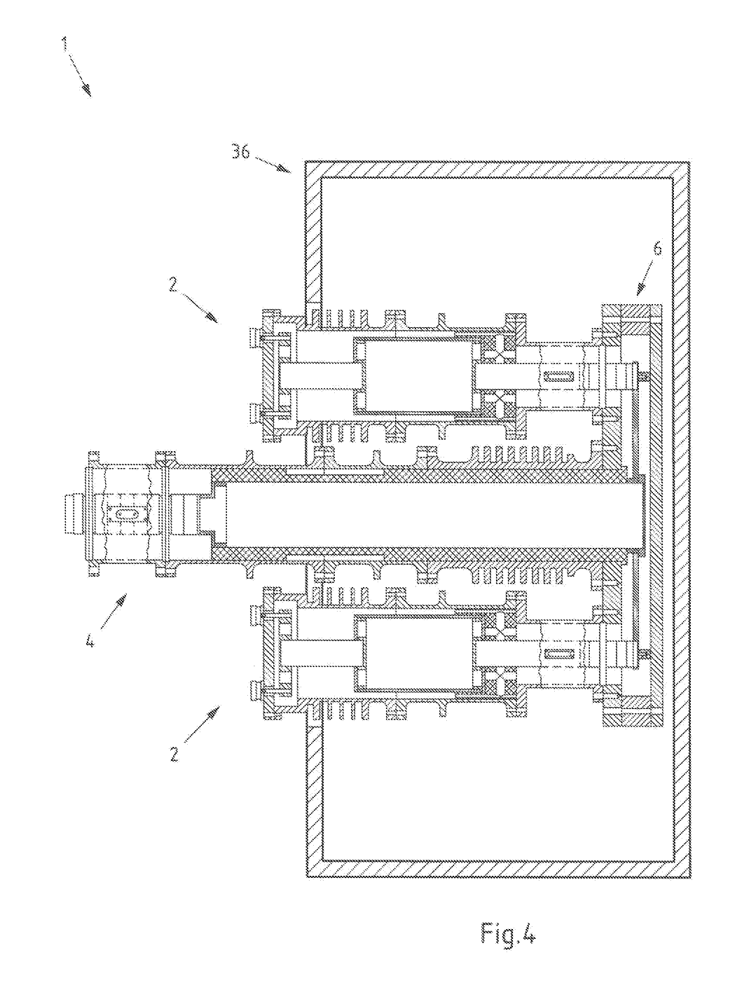

FIG. 4 shows a longitudinal view of the embodiment of the combiner arrangement 1 from FIG. 1 arranged in a control cabinet 36. As can be seen, the combiner arrangement can be arranged in the control cabinet 36. Coaxial cables can be connected to the ends of the primary combiners 2 lying at a distance from the disc-shaped coupler 6, which supply high-frequency input signals from amplifier units (not shown) to the combiner arrangement 1, which amplifier units are accommodated in other control cabinets, for example. The high-frequency output signal can also be decoupled easily and without problems from the combiner arrangement 1 at the end of the elongated line section 4 lying at a distance from the disc-shaped coupler 6.

1. A combiner arrangement for combining a plurality of high-frequency input signals into a high-frequency output signal comprising:
at least two primary combiners for combining at least two high-frequency input signals into a high-frequency intermediate signal and
a secondary combiner for combining the high-frequency intermediate signals of the primary combiners into the high-frequency output signal,
wherein the secondary combiner comprises a coupler for combining the high-frequency intermediate signals of the primary combiners.

2. The combiner arrangement according to claim 1,
wherein the coupler in the secondary combiner is disc-shaped.

3. The combiner arrangement according to claim 1,
wherein the secondary combiner is configured such that an at least partial compensation of the high-frequency signals reflected in the secondary combiner is achieved.

4. The combiner arrangement according to claim 3,
wherein the high-frequency signals reflected in the secondary combiner are compensated by a further specific reflection of high-frequency signals in the secondary combiner.

5. The combiner arrangement according to claim 1,
wherein at least one characteristic geometric extension of the coupler in the secondary combiner is not insignificant compared with the wavelength of the high-frequency input signals and/or the high-frequency output signal.

6. The combiner arrangement according to claim 1,
wherein the primary combiners are each configured substantially in an elongated manner, wherein the primary combiners run substantially parallel and/or are substantially perpendicular to the coupler of the secondary combiner.

7. The combiner arrangement according to claim 1,
wherein the secondary combiner has a substantially elongated line section, which runs substantially parallel to the primary combiner and/or is substantially perpendicular to the coupler of the secondary combiner.

8. The combiner arrangement according to claim 7,
wherein the substantially longitudinal line section of the secondary combiner is arranged centrally on the coupler of the secondary combiner and the primary combiners are arranged around the substantially longitudinal section of the secondary combiner on the coupler of the secondary combiner.

9. The combiner arrangement according to claim 1,
wherein the primary combiners and/or the secondary combiner are configured as coaxial conductors at least in sections.

10. The combiner arrangement according to claim 9,
wherein the primary combiners and/or the secondary combiner are dielectrically loaded at least in sections.

11. The combiner arrangement according to claim 1,
wherein the coupler in the secondary combiner has a hollow space with an inner coupling conductor arranged therein.

12. The combiner arrangement according to claim 11,
wherein the coupler in the secondary combiner is configured as a parallel plate conductor.

13. The combiner arrangement according to claim 1,
wherein the primary combiners at least in part, each have a collector section with connections for coupling the high-frequency input signals.

14. The combiner arrangement according to claim 13,
wherein the collector sections of the primary combiners at least in part, each have a disc-shaped coupler for combining the high-frequency input signals.

15. The combiner arrangement according to claim 1,
wherein the primary combiners at least in part, each have a transformer section for adjusting the waveguide impedance, wherein the waveguide impedance is adjusted in stages.

16. The combiner arrangement according to claim 1,
wherein the primary combiners at least in part, each have integrated bidirectional couplers.

17. The combiner arrangement according to claim 1,
wherein the combiner arrangement is configured to provide a high-frequency output signal with an output of at least 50 kW.

18. The combiner arrangement according to claim 1,
wherein the combiner arrangement is configured to combine high-frequency input signals of the same phase and/or same amplitude with an output of at least 1 kW.

19. The combiner arrangement according to claim 1,
wherein the combiner arrangement is configured to combine high-frequency input signals with a frequency of at least 30 MHz and/or at most 500 MHz.

20. The combiner arrangement according to claim 1,
wherein at least four primary combiners are provided to combine the at least two high-frequency input signals into the respective high-frequency intermediate signal.

21. The combiner arrangement according to claim 1,
wherein the primary combiners and/or the secondary combiner are made at least partly of copper and/or aluminium.

22. A system comprising
a plurality of amplifier units to generate the high-frequency input signals and
the combiner arrangement according to claim 1.

23. A method for combining a plurality of high-frequency input signals into a high-frequency output signal, in particular with the combiner arrangement according to claim 1 comprising the steps:
combining at least two high-frequency input signals into a high-frequency intermediate signal by means of at least two primary combiners and
combining the high-frequency intermediate signals of the primary combiners into the high-frequency output signal by means of a secondary combiner,
wherein the high-frequency intermediate signals of the primary combiners are combined by means of a coupler of the secondary combiner.
